(19) United States
(12) Patent Application Publication
(10) Pub. No.: US 2014/0265735 A1
(43) Pub. Date: Sep. 18, 2014

(54) PIEZOELECTRIC VIBRATING PIECE AND PIEZOELECTRIC DEVICE

(71) Applicant: NIHON DEMPA KOGYO CO., LTD., Tokyo (JP)

(72) Inventors: SHINICHI ASANO, MIYAGI (JP); TAKEHIRO TAKAHASHI, SAITAMA (JP)

(73) Assignee: NIHON DEMPA KOGYO CO., LTD., Tokyo (JP)

(21) Appl. No.: 14/203,567

(22) Filed: Mar. 11, 2014

(30) Foreign Application Priority Data
Mar. 13, 2013 (JP) 2013-050283

(51) Int. Cl. H01L 41/047

(52) U.S. Cl. CPC H01L 41/047
USPC 310/365

(57) ABSTRACT

A piezoelectric vibrating piece includes a vibrator, a framing portion that surrounds the vibrator, a connecting portion that connects the vibrator and the framing portion, an excitation electrode on each of a front surface and a back surface of the vibrator, and a first extraction electrode and a second extraction electrode on the framing portion. The first extraction electrode and the second extraction electrode are electrically connected to the respective excitation electrodes. The piezoelectric vibrating piece includes a front surface and a back surface. A stepped portion is disposed on at least one of the front surface and the back surface of the piezoelectric vibrating piece. In a case where one of the first extraction electrode and the second extraction electrode is disposed across the stepped portion, another one of the first extraction electrode and the second extraction electrode is disposed to avoid crossing over the stepped portion.

### CROSS REFERENCE TO RELATED APPLICATIONS

This application claims the priority benefit of Japan application serial no. 2013-050283, filed on Mar. 13, 2013. The entirety of the above-mentioned patent application is hereby incorporated by reference herein and made a part of this specification.

### TECHNICAL FIELD

This disclosure relates to a piezoelectric vibrating piece and a piezoelectric device.

### DESCRIPTION OF THE RELATED ART

Electronic equipment such as a mobile terminal and a mobile phone includes a piezoelectric device such as a crystal unit and a crystal oscillator. This type of known piezoelectric device includes a configuration having a piezoelectric vibrating piece such as a quartz crystal piece, a lid portion, and a base portion. The piezoelectric vibrating piece includes a vibrator, which vibrates at a predetermined vibration frequency, a framing portion, which surrounds the vibrator, and a connecting portion, which connects the vibrator and the framing portion. In this type of the piezoelectric vibrating piece, the base portion and the lid portion are respectively bonded on a surface (one principal surface) and a back surface (the other principal surface) of the framing portion via bonding material. The vibrator of the piezoelectric vibrating piece includes respective excitation electrodes on the front surface and the back surface. Extraction electrodes are formed from the respective excitation electrodes to the framing portion. This configuration is disclosed in Japanese Unexamined Patent Application Publication No. 2009-65437.

These excitation electrodes and the extraction electrodes are formed by, for example, the following process. First, a metal film is formed all over a front surface and a back surface of a crystal wafer by sputtering method. Next, a resist is applied over the surface of the metal film, and this resist film is exposed and developed using a predetermined pattern. Next, a predetermined portion of the metal film is removed by etching or a similar process, and the remaining resist film is removed to form a desired pattern (excitation electrodes and extraction electrodes) on the metal film.

However, in the case where the crystal wafer has a stepped portion, it is difficult to remove the resist film at a peripheral edge portion of the stepped portion in the development process. Thus, the resist film may partially remain. If the resist film remains, the metal film is not removed by etching process. Thus, the electrodes are formed in a state where the metal film that should be removed remains. Accordingly, for example, in the case where multiple electrodes in parallel are formed across the same stepped portion, the metal film remains so as to connect the multiple electrodes. As a result, a short circuit between the multiple electrodes occurs and causes a problem of an operation failure.

A need thus exists for a piezoelectric vibrating piece and a piezoelectric device which are not susceptible to the drawbacks mentioned above.

### SUMMARY

A piezoelectric vibrating piece according to the disclosure includes a vibrator, a framing portion that surrounds the vibrator, a connecting portion that connects the vibrator and the framing portion, an excitation electrode on each of a front surface and a back surface of the vibrator, and a first extraction electrode and a second extraction electrode on the framing portion. The first extraction electrode and the second extraction electrode are electrically connected to the respective excitation electrodes. The piezoelectric vibrating piece includes a front surface and a back surface. A stepped portion is disposed on at least one of the front surface and the back surface of the piezoelectric vibrating piece. In a case where one of the first extraction electrode and the second extraction electrode is disposed across the stepped portion, another one of the first extraction electrode and the second extraction electrode is disposed to avoid crossing over the stepped portion.

### BRIEF DESCRIPTION OF THE DRAWINGS

FIG. 1 is a plan view illustrating a configuration of a piezoelectric vibrating piece according to a first embodiment.

FIG. 2A is a cross-sectional view of the piezoelectric vibrating piece taken along the line A-A of FIG. 1.

FIG. 2B is a cross-sectional view of the piezoelectric vibrating piece taken along the line B-B of FIG. 1.

FIG. 3 is a plan view of an enlarged main section of a comparative example of a piezoelectric vibrating piece.

FIG. 4 is a plan view of a piezoelectric vibrating piece according to a second embodiment.

FIG. 5A is a cross-sectional view of the piezoelectric vibrating piece taken along the line C-C of FIG. 4.

FIG. 5B is a cross-sectional view of the piezoelectric vibrating piece taken along the line D-D of FIG. 4.

FIG. 6 is an exploded perspective view of a piezoelectric device according to an embodiment.

FIG. 7 is a cross-sectional view of the piezoelectric device taken along the line E-E of FIG. 6.

### DETAILED DESCRIPTION

Hereinafter, embodiments of this disclosure will be described with reference to the attached drawings. It will be understood that the scope of the disclosure is not limited to the described embodiments. In the following embodiments, a scale of an expressed drawing is adjusted to explain an embodiment. For example, a part of a drawing is enlarged or stressed as required when it is described. In drawings, metal film and bonding material areas are illustrated with a hatching pattern. Each of the following drawings uses an XYZ coordinate system to describe directions in the drawings. In this XYZ coordinate system, a plane parallel to the front surface of a piezoelectric vibrating piece is assumed to be an XZ plane. On this XZ plane, a longitudinal direction of the piezoelectric vibrating piece is indicated as X direction, and a direction orthogonal to the X direction is indicated as Z direction. A direction perpendicular to the XZ plane (thickness direction of a piezoelectric vibrating piece) is indicated as Y direction. In the description, a direction pointed by an arrow is assumed to be a + direction in each of X, Y, and Z directions. The direction opposite of that is assumed to be a − direction.

### First Embodiment

A piezoelectric vibrating piece 130 according to a first embodiment of the disclosure will be described by referring to FIG. 1 and FIG. 2. FIG. 1 is a transparent view illustrating a plane of the piezoelectric vibrating piece 130. FIG. 1 also illustrates a back surface configuration of the piezoelectric vibrating piece 130 by projecting it from its front surface side. As a piezoelectric vibrating piece 130, for example, an AT-cut quartz-crystal vibrating piece is used. AT-cut has advantages that satisfactory frequency characteristics are obtained when a piezoelectric device such as a crystal unit is used at around ordinary temperature for example, and is a processing method for cutting out the quartz crystal at an angle inclined at 35° 15′ around the crystallographic axis with respect to the optical axis among the electric axis, the mechanical axis, and the optical axis, which are three crystallographic axes of the synthetic quartz crystal.

As illustrated in FIG. 1, the piezoelectric vibrating piece 130 includes a vibrator 131, a framing portion 132, and a connecting portion 133. The vibrator 131 vibrates at a predetermined vibration frequency. The framing portion 132 surrounds the vibrator 131. The connecting portion 133 connects the vibrator 131 and the framing portion 132. Between the vibrator 131 and the framing portion 132, a through hole 134 is formed. This through hole 134 penetrates through in the Y-axis direction and is not formed at the connecting portion 133. The vibrator 131, when viewed in the Y direction, is formed into a rectangular shape that has long sides in the X-axis direction and short sides in the Z-axis direction. The vibrator 131 also has a mesa portion 135 in the center as well as a mesa peripheral portion 136 at a periphery of the mesa portion 135, which is thinner than the mesa portion 135. The whole mesa portion 135 is entirely formed at a uniform thickness. The mesa peripheral portion 136 includes a region contacting the mesa portion 135 with a thickness slightly thinner than the thickness of the mesa portion 135. This, however, should not be construed in a limiting sense. For example, the mesa peripheral portion 136 may have a thickness that gradually decreases from the mesa portion 135 (not shown).

As illustrated in FIG. 1 and FIGS. 2A and 2B, on a back surface 136b of the mesa peripheral portion 136, a projecting portion 137, which is an extension of a back surface 133b in the +X direction, is formed. The back surface 136b is connected to the back surface 133b of the connecting portion 133. The connecting portion 133 has a thickness that is maintained up to a portion of the back surface 136b of the mesa peripheral portion 136 (vibrator 131). This projecting portion 137 is protruded from the back surface 136b of the mesa peripheral portion 136 in the −Y direction. Thus, the formation of the projecting portion 137 increases the strength of the area between the vibrator 131 (the mesa peripheral portion 136) and the connecting portion 133.

At the +X side of the projecting portion 137, an X-side stepped portion (stepped portion) 138 is formed. At the −Z side of the projecting portion 137, a −Z-side stepped portion (stepped portion) 139 is formed. At the +Z side of the projecting portion 137, a +Z-side stepped portion (stepped portion) 140 is formed. As illustrated in FIG. 1, between the X-side stepped portion 138 and the −Z-side stepped portion 139, a corner portion of the projecting portion 137 is interposed. Likewise, between the X-side stepped portion 138 and the +Z-side stepped portion 140, a corner portion of the projecting portion 137 is interposed. Therefore, on the XZ plane, the X-side stepped portion 138 has a substantially orthogonal positional relation with the −Z-side stepped portion 139. Similarly, the X-side stepped portion 138 has a substantially orthogonal positional relation with the +Z-side stepped portion 140. However, formation of the projecting portion 137 is optional. In an example of embodiments, the X-side stepped portion 138 may be formed at a boundary area between the connecting portion 133 and the mesa peripheral portion 136. Furthermore, the projecting portion 137 is not limited to be formed at the back surface 136b (−Y side) of the mesa peripheral portion 136. The projecting portion 137 may be formed at a front surface 136a (+Y side).

On a front surface 135a (+Y-side surface) of the mesa portion 135 of the vibrator 131, a rectangular-shape excitation electrode 141 is formed, while on a back surface (−Y-side surface) 135b, a similarly rectangular-shape excitation electrode 142 is formed. FIG. 1 illustrates the back surface side of the vibrator 131 (the mesa portion 135) viewed in projection, and illustrates the excitation electrode 142. The excitation electrode 141 and the excitation electrode 142 are respectively connected to a first extraction electrode 143 and a second extraction electrode 144.

The first extraction electrode 143 is extracted from the −X side of the excitation electrode 141, via the front surface 135a of the mesa portion 135, the front surface 136a of the mesa peripheral portion 136, and the front surface 133a of the connecting portion 133, to the −X-side front surface 132a of the framing portion 132. The first extraction electrode 143 is then formed into a rectangular shape at a region at the −X side and −Z side. The region includes the front surface 132a of the framing portion 132 and the front surface 136a of the mesa peripheral portion 136. As illustrated in FIG. 1, the first extraction electrode 143 is connected via a region at the −X side and −Z side on a side surface 131a of the vibrator 131, a region at the −X side and −Z side on an inner side surface 132c of the framing portion 132, and a −Z-side of a side surface 133c of the connecting portion 133 and then connected to a back surface side electrode 143a, which is formed in a region at the −X side and −Z side. This region includes a back surface 132b of the framing portion 132 and the back surface 136b of the mesa peripheral portion 136.

The back surface side electrode 143a is formed to substantially overlap the first extraction electrode 143 when viewed in the Y direction. The first extraction electrode 143 is formed on portions such as the framing portion 132, connecting portion 133, and a front surface 132a of the vibrator 131. The back surface side electrode 143a is also a rectangular electrode formed in a rectangular shape in a rectangular region at the −X side and −Z side. This region includes the back surface 132b of the framing portion 132 and the back surface 136b of the mesa peripheral portion 136.

As illustrated in FIG. 1, the second extraction electrode 144 is extracted from the −X side of the excitation electrode 142, via the back surface 135b of the mesa portion 135, the back surface 136b of the mesa peripheral portion 136, and the back surface 133b of the connecting portion 133, to the −X-side back surface 132b of the framing portion 132. Furthermore, the second extraction electrode 144 is extended on the back surface 132b of the framing portion 132 in the +Z direction, then folded in the +X direction, and formed up to a region at the +X-side and +Z-side on the back surface 132b of the framing portion 132. The +X-side and +Z-side region of this second extraction electrode 144 is located diagonal to the back surface side electrode 143a of the first extraction electrode 143. The excitation electrode 141 and the excitation electrode 142 are not electrically connected.

As illustrated in FIG. 1 and FIG. 2B, the second extraction electrode 144 is also extracted from the −X side of the excitation electrode 142 into the −X direction in a strip shape and across the X-side stepped portion 138. On the other hand, the back surface side electrode 143a of the first extraction electrode 143 is formed to avoid crossing over the X-side stepped portion 138, and is formed across the −Z-side stepped portion 139. In other words, the second extraction electrode 144 and the back surface side electrode 143a are not disposed across the same stepped portion (such as the X-side stepped portion 138) in parallel, but the second extraction electrode 144 and the back surface side electrode 143a are disposed across receptive different stepped portions.

The excitation electrodes 141 and 142, the first extraction electrode 143 (which includes the back surface side electrode 143a), and the second extraction electrode 144 each have a two-layer structure. For example, the two-layer structure contains a first metal layer, which has a conductive property and formed on a surface of a quartz-crystal material constituting the piezoelectric vibrating piece 130, and a second metal layer, which has a conductive property and laminated and formed on the first metal layer. The first metal layer has a role of improving adhesion of the respective electrodes against a quartz-crystal material. For example, materials such as nickel tungsten (NiW) are employed to form the layer. The second metal layer has a role of protecting electrodes and ensuring conductive properties. For example, materials such as gold (Au) are employed to form the layer. Gold (Au) is chemically stable and protects electrodes from corrosion and similar trouble. Chrome (Cr) or another material may be used to form a foundation layer for these metal layers to constitute a three-layer structure.

Thus, according to the first embodiment, the first extraction electrode 143 (which includes the back surface side electrode 143a) and the second extraction electrode 144 are disposed to avoid crossing over the same stepped portion (such as the X-side stepped portion 138). This disposition prevents a short circuit between the two electrodes, inhibits decrease of a resistance value between the two electrodes, and provides a piezoelectric vibrating piece with suppressed operation failure and high reliability. For the piezoelectric vibrating piece 130, the two extraction electrodes are disposed not to cross over the same stepped portion on the back surface of the piezoelectric vibrating piece 130. A similar disposition is applied when the two electrodes are formed on the front surface of the piezoelectric vibrating piece 130.

Next, a manufacturing method of the piezoelectric vibrating piece 130 will be described. When manufacturing the piezoelectric vibrating pieces 130, multiple pieces are cut out individually from a piezoelectric wafer. A piezoelectric wafer is prepared first. A piezoelectric wafer is cut out from quartz crystal by AT-cut. Next, a piezoelectric wafer contains regions that correspond to a plurality of piezoelectric vibrating pieces 130. On each of the regions, the vibrator 131, the framing portion 132, and the connecting portion 133 are formed by photolithography and etching (main body formation process). Here, the framing portion 132 surrounds the vibrator 131, and the connecting portion 133 connects the vibrator 131 and the framing portion 132. Between the vibrator 131 and the framing portion 132, the through hole 134 is formed. Subsequently, the Y-direction thickness of the vibrator 131 and the connecting portion 133, excluding the framing portion 132, is formed to be thinner than the framing portion 132 by etching or a similar process so as to adjust for the vibrator 131 to have a desired frequency characteristic. For the Y-direction thickness adjustment of the vibrator 131 and the connecting portion 133, machining methods such as cutting may also be applied.

Subsequently, the vibrator 131 is formed to have its peripheral regions on the front and back surfaces to be thinner toward the Y direction by a method such as photolithography and etching. This process forms the mesa portion 135 and the mesa peripheral portion 136 surrounding the mesa portion 135. When this mesa peripheral portion 136 is formed, a patterning is performed so that a partial region of the mesa peripheral portion 136 that is connected to the back surface 133b of the connecting portion 133 comes in continuation with the back surface 133b. This consequently forms a projecting portion 137. This projecting portion 137 forms each of the X-side stepped portion 138, the −Z-side stepped portion 139, and the +Z-side stepped portion 140. The manufacturing process to form the mesa portion 135 may be a machining method such as cutting. Furthermore, the projecting portion 137 is not limited to be formed simultaneously with the mesa portion 135. The projecting portion 137 may be formed before or after the formation of the mesa portion 135.

Subsequently, on the front surface 135a of the mesa portion 135 of the vibrator 131, the excitation electrode 141 is formed, and the excitation electrode 142 is formed on the back surface 135b of the mesa portion 135. On the vibrator 131, the connecting portion 133, and the framing portion 132, the excitation electrodes 141 and 142 and the first extraction electrodes 143 (which includes the back surface side electrode 143a) and 144, which are respectively and electrically connected to the excitation electrodes 141 and 142, are formed. When these electrodes are formed, a conductive metal film is formed first. Then on this metal film, a resist film is laminated. After a patterning is performed on this resist film by exposure and development, then predetermined portions on the metal film are removed by etching, then the resist film is removed. The metal film is formed, for example, from the front or back surface of the piezoelectric wafer by vacuum evaporation or sputtering.

As a conductive metal film, for example, a two-layer structured metal film of a nickel tungsten (Ni—W) film and a gold (Au) film on this nickel tungsten film is formed. As a foundation layer for these metal films, a chrome (Cr) film may be formed. This type of process forms a plurality of main bodies of the piezoelectric vibrating pieces 130 on a piezoelectric wafer. Subsequently, a wafer formed with lid portions and a wafer formed with base portions, which will be described later, are bonded to a piezoelectric wafer. Then, these bonded wafers are diced (diced processing) to make individual piezoelectric vibrating pieces 130 (piezoelectric device).

While the second extraction electrode 144 is formed across the X-side stepped portion 138, the back surface side electrode 143a is formed across the −Z-side stepped portion 139. Because of this, for example, even in the case where a metal film remains on the X-side stepped portion 138 in etching, the two electrodes do not electrically connect, thus preventing a short circuit between the two electrodes. Thus, the state of a remaining metal film on the X-side stepped portion 138 is described with a comparative example of FIG. 3.

FIG. 3 illustrates a piezoelectric vibrating piece 130a according to a comparative example. Like reference numerals designate corresponding or identical elements to those of the first embodiment, and therefore such elements will not be further elaborated here. In FIG. 3, the connecting portion 133 of FIG. 1 and the portions equivalent to its peripheral are enlarged in a plan view. The piezoelectric vibrating piece 130a is different from the piezoelectric vibrating piece 130 of FIG. 1 in that the back surface side electrode 143b of the first extraction electrode 143 is formed in a rectangular shape across the X-side stepped portion 138. Therefore, at the piezoelectric vibrating piece 130a, the second extraction electrode 144 and the back surface side electrode 143b cross over the identical X-side stepped portion 138 in parallel.

Here, among the above-described processes of forming electrodes, patterning of the resist film is studied. In exposure and development, the X-side stepped portion 138 blocks the exposure light and reduces the irradiation amount, and this leads to an exposure light failure at a peripheral edge portion of the stepped portion 138, causing a remaining resist in some cases. Even with proper exposure, there is a case where the resist film at the peripheral edge of the X-side stepped portion 138 remains without being removed at development.

Thus, if an etching is performed on a metal film with resist film partially remained, the metal film on that portion is not removed. The metal film on the portion remains even after all the resist film is removed. As illustrated in FIG. 3, this remaining metal film results in an electrical connection between the second extraction electrode 144 and the back surface side electrode 143b, and leads to an operation failure of the piezoelectric vibrating piece 130a. The electrically connected portion is called a short circuit portion S.

On the other hand, as described earlier, at the piezoelectric vibrating piece 130 of the first embodiment, the back surface side electrode 143a and the second extraction electrode 144 are disposed to avoid crossing over the same stepped portion (such as the X-side stepped portion 138). Thus, even if the metal film (the short circuit portion S) as illustrated in FIG. 3 is produced, the two electrodes will not be electrically connected.

### Second Embodiment

Next, a description will be given of the second embodiment. In the following descriptions, like reference numerals designate corresponding or identical elements to those of the first embodiment, and therefore such elements will not be further elaborated here. FIG. 4 illustrates a piezoelectric vibrating piece 230 according to the second embodiment. Similarly to FIG. 1, FIG. 4 illustrates a back surface configuration of the piezoelectric vibrating piece 230 by projecting it from its front surface side. This piezoelectric vibrating piece 230 is different from the piezoelectric vibrating piece 130 of the first embodiment in that the piezoelectric vibrating piece 230 includes a stepped portion (framing portion side stepped portion 238) formed in a boundary portion between the framing portion 132 and the connecting portion 133, and a back surface side electrode 234a is formed by avoiding this stepped portion.

As illustrated in FIG. 4, FIG. 5A, and FIG. 5B, the framing portion side stepped portion (stepped portion) 238 is formed such that the back surface 133b of the connecting portion 133 is displaced with respect to the back surface 132b of the framing portion 132 in the +Y direction. Therefore, the second extraction electrode 144 is extracted in the −X direction from the excitation electrode 142 and crosses over each of the X-side stepped portion 138 and the framing portion side stepped portion 238. On the piezoelectric vibrating piece 230, the projecting portion 137 (such as the X side stepped portion 138) is disposed. This, however, should not be construed in a limiting sense. For example, the back surface 133b of the connecting portion 133 and the back surface 136b of the mesa peripheral portion 136 may forms a flush surface, and the mesa peripheral portion 136 (connecting portion 133) may have no stepped portion formed.

In the extraction electrode 243 extracted from the excitation electrode 141, the back side electrode 243a, which is extracted to the back surface 132b of the framing portion 132, is formed only on the back surface 132b of the framing portion 132, and not formed on the mesa peripheral portion 136 or the connecting portion 133. In other words, the back surface side electrode 243a is disposed to avoid crossing over the framing portion side stepped portion 238. Therefore, the second extraction electrode 144 and the back surface side electrode 243a do not cross over the same framing portion side stepped portion 238 in parallel. As a result, even if the framing portion side stepped portion 238 has a remaining metal film (see the short circuit portion S in FIG. 3), there is no possibility for the second extraction electrode 144 to be electrically connected to the back surface side electrode 243a.

Thus, according to the second embodiment, both of the back surface side electrode 243a and the second extraction electrode 144 are disposed to avoid crossing over the framing portion side stepped portion 238, which is formed between the framing portion 132 and the connecting portion 133. Similarly to the first embodiment, this disposition prevents a short circuit between the two electrodes and provides a highly reliable piezoelectric vibrating piece with suppressed operation failure.

At the back surface of the piezoelectric vibrating piece 230, the back surface side electrode 243a and the second extraction electrode 144 are disposed to avoid crossing over the identical framing portion side stepped portion 238. This is similar when both the electrodes are formed on the front surface of the piezoelectric vibrating piece 230. This manufacturing method of the piezoelectric vibrating piece 230 is substantially similar to that of the first embodiment. The framing portion side stepped portion 238 may be formed simultaneously with the formation of the mesa peripheral portion 136 (the mesa portion 135). The framing portion side stepped portion 238 may be formed before or after the formation of the mesa peripheral portion 136.

While the first and second embodiments of the piezoelectric vibrating pieces were described above, this disclosure is not limited to the above-described embodiments, and various changes of the embodiments may be made without departing from the spirit and scope of the disclosure. In the above-described embodiments, the configuration with the vibrator 131 that includes the mesa portion 135 and the mesa peripheral portion 136 was employed as an example. This, however, should not be construed in a limiting sense. The configuration may be without the mesa portion 135 (and the mesa peripheral portion 136).

### Piezoelectric Device

Next, a description will be given of an embodiment of a piezoelectric device. As illustrated in FIG. 6 and FIG. 7, the piezoelectric device 100 has a configuration where the piezoelectric vibrating piece 130 is sandwiched by a lid portion 110 and a base portion 120. The lid portion 110 is formed at the +Y side of the piezoelectric vibrating piece 130, and the base portion 120 is formed at the −Y side of the piezoelectric vibrating piece 130. The lid portion 110 and the base portion 120, similarly to the piezoelectric vibrating piece 130, employ, for example, an AT-cut quartz-crystal material. As a piezoelectric vibrating piece 130, the piezoelectric vibrating piece 130 of the first embodiment illustrated in FIG. 1 is employed.

The lid portion 110 is formed in a rectangular plate shape as illustrated in FIG. 6 and FIG. 7, and includes a depressed portion 111 formed on the back surface (the surface at the −Y side) and a bonding surface 112 that surrounds the depressed portion 111. The bonding surface 112 faces a front surface 132a of the framing portion 132 of the piezoelectric vibrating piece 130. As illustrated in FIG. 7, the lid portion 110 is bonded to the front surface (the surface side at +Y side) of the piezoelectric vibrating piece 130 by a bonding material 150, which is disposed between the bonding surface 112 and the front surface 132a of the framing portion 132. As the bonding material 150, for example, low-melting glass, which has non-conductive property, is employed. Instead of this, resins such as polyimide may also be used.

The base portion 120 is formed in a rectangular plate shape as illustrated in FIG. 6 and FIG. 7, and includes a depressed portion 121 formed on the front surface (the surface at +Y side) and a bonding surface 122 that surrounds the depressed portion 121. The bonding surface 122 faces a back surface 132b of the framing portion 132 of the piezoelectric vibrating piece 130. As illustrated in FIG. 7, the base portion 120 is bonded to the back surface (the surface side at −Y side) of the piezoelectric vibrating piece 130 by a bonding material 150, which is disposed between the bonding surface 122 and the back surface 132b of the framing portion 132.

Castellations 123 and 123a, which are partially cutout portions, are formed in two corner portions (a corner portion at the +X side and +Z side, and a corner portion at the −X side and −Z side) diagonal to each other among four corner portions of the base portion 120. At the back surface (the surface at −Y side) of the base portion 120, external electrodes 126 and 126a are respectively disposed as a mounting terminal pair.

At the castellations 123 and 123a, castellation electrodes 124 and 124a are respectively formed. Furthermore, on the front surface (+Y side surface) of the base portion 120, which is also a region surrounds the castellations 123 and 123a, connection electrodes 125 and 125a are respectively formed. These connection electrodes 125 and 125a and the external electrodes 126 and 126a are electrically connected together via the castellation electrodes 124 and 124a. The castellations 123 and 123a are not limited to be disposed at corner portions. The castellations 123 and 123a may be disposed at side portions.

The castellation electrodes 124 and 124a, the connection electrodes 125 and 125a, and the external electrodes 126 and 126a are formed integrally as a conductive metal film, for example, by sputtering using a metal mask or by vacuum evaporation. These electrodes may also be separately formed. These electrodes employs a metal films that has, for example, a three-layer structure where a chrome (Cr) layer, a nickel tungsten (Ni—W) layer, and a gold (Au) layer are laminated in this order. Chrome is used for its excellence in adhesion to quartz-crystal materials and to improve a corrosion resistance of a metal film by diffusing to the nickel tungsten layer and forming an oxide film (passivation film) on the exposed surface of the nickel tungsten layer.

As a metal film, a two-layer structure where a nickel tungsten (Ni—W) layer and a gold (Au) layer are laminated in this order may also be used. Also, for example, aluminum (Al), titanium (Ti), or alloy of these materials may be used instead of chrome. Additionally, for example, nickel (Ni) or tungsten (W) may be used instead of nickel tungsten. Furthermore, for example, silver (Ag) may be used instead of gold.

The connection electrode 125 of the base portion 120 is electrically connected to the second extraction electrode 144 of the piezoelectric vibrating piece 130. The connection electrode 125a is electrically connected to the back surface side electrode 143a of the first extraction electrode 143. However, the connection configuration is not limited to a configuration using the connection electrodes 125 and 125a. For example, in another connection configuration, the base portion 120 may be connected to the piezoelectric vibrating piece 130 first, then while the external electrodes 126 and 126a are formed, a metal film may be extended from the external electrodes 126 and 126a via the castellations 123 and 123a to the second extraction electrode 144 and the back surface side electrode 143a.

Next, a description will be given of a manufacturing method of a piezoelectric device 100. Various processes regarding a piezoelectric wafer (the manufacturing method of the piezoelectric vibrating piece 130) are similar to the processes described above. Redundant descriptions are omitted or simplified. Concurrently with the manufacturing of the piezoelectric vibrating piece 130, the lid portion 110 and the base portion 120 are fabricated. For these lid portion 110 and base portion 120, similarly to the piezoelectric vibrating pieces 130, multiple individual portions are cut out from a lid wafer and a base wafer respectively.

First, a lid wafer and a base wafer are prepared along with a piezoelectric wafer. For each wafer, wafers cut out from a quartz crystal by AT cut are used, similarly to the piezoelectric wafer. The reason for that is as follows. The manufacturing process of the piezoelectric device 100 includes a process of bonding wafers and a process of forming a metal film on wafer surfaces. In these processes, each wafer is heated and expanded by heat. If wafer materials with different expansion rates are used, difference in expansion rates may cause troubles such as deformation and a crack.

On the back surface of the lid wafer, a depressed portion 111 is formed by photolithography and etching. On the front surface of the base wafer, a depressed portion 121 and castellations 123 and 123a are formed by photolithography and etching. Processing on the lid water and base wafer may be a machining method instead of etching. Furthermore, on prescribed portions on the base wafer, castellation electrodes 124 and 124a, connection electrodes 125 and 125a, and external electrodes 126 and 126a are each formed by sputtering using a metal mask or by vacuum evaporation.

Subsequently, under vacuum atmosphere, the lid wafer is bonded to the front surface of the piezoelectric wafer by sandwiching a bonding material 150 while the base wafer is also bonded to the back surface of the piezoelectric wafer by sandwiching a bonding material 150. The bonding material 150, which is made of materials such as low-melting glass, is heated and applied in a fused state, and when the bonding material 150 solidifies, it bonds different wafers. Subsequently, the bonded wafers are cut along preliminarily designed scribe lines to complete individual piezoelectric devices 100.

Thus, the piezoelectric device in the above-described embodiment employs the piezoelectric vibrating piece 130, which reduces occurrence of operation failure, and improves the operational reliability. In the above-described embodiment, the piezoelectric vibrating piece 130 described in the first embodiment is used. Instead of this, the piezoelectric vibrating piece 230 described in the second embodiment may also be used.

The embodiment of the piezoelectric device has been described above. However, this disclosure is not limited to the above-described embodiment, and various changes of the embodiment may be made without departing from the spirit and scope of the disclosure. Additionally, although the above-described embodiment illustrates a crystal unit (a piezoelectric resonator) as a piezoelectric device, an oscillator is also possible. In the case of an oscillator, an IC or similar member is mounted on the base portion 120. Then, the extraction electrode 141 and similar member in the piezoelectric vibrating piece 130 and the external electrodes 126 and 126a of the base portion 120 each connect to the IC or similar member. In the above-described embodiment, as the lid portion 110 and the base portion 120, an AT-cut crystal material similar to the piezoelectric vibrating piece 130 is used. Instead of this, another crystal material, glass, ceramic and other materials may also be used.

The stepped portion may be constituted on a front surface or a back surface of the vibrator using a configuration where the connecting portion has a thickness that is maintained up to a portion of the vibrator and then the vibrator decreases in thickness. The connecting portion may include a mesa portion at a central portion and a mesa peripheral portion that is thinner than the mesa portion. The first extraction electrode may include a back surface side electrode extracted from a front surface of the framing portion to a back surface of the framing portion, and this back surface side electrode may be disposed to avoid crossing over the stepped portion in a case where the second extraction electrode is disposed across the stepped portion. The disclosure provides a piezoelectric device that includes the above-described piezoelectric vibrating piece.

This disposition prevents a short circuit between the first extraction electrode and the second extraction electrode and suppresses operation failure, thus providing a highly reliable piezoelectric vibrating piece and piezoelectric vibrating piece.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrator;
a framing portion that surrounds the vibrator;
a connecting portion that connects the vibrator and the framing portion;
an excitation electrode, being disposed on each of a front surface and a back surface of the vibrator;
a first extraction electrode and a second extraction electrode, being disposed on the framing portion, the first extraction electrode and the second extraction electrode being electrically connected to the respective excitation electrodes, wherein
the piezoelectric vibrating piece includes a front surface and a back surface, a stepped portion being disposed on at least one of the front surface and the back surface of the piezoelectric vibrating piece, and
in a case where one of the first extraction electrode and the second extraction electrode is disposed across the stepped portion, another one of the first extraction electrode and the second extraction electrode is disposed to avoid crossing over the stepped portion.

2. The piezoelectric vibrating piece according to claim 1, wherein
the stepped portion is formed by the connecting portion with a thickness that is maintained up to a portion of the vibrator and by the vibrator with a thickness that decreases from the portion.

3. The piezoelectric vibrating piece according to claim 2, wherein
the vibrator includes:
a mesa portion, being disposed at a central portion; and
a mesa peripheral portion, being disposed at a periphery of the mesa portion, the mesa peripheral portion being thinner than the mesa portion, wherein
the stepped portion is disposed at the mesa peripheral portion.

4. The piezoelectric vibrating piece according to claim 1, wherein
the first extraction electrode includes a back surface side electrode, and the back surface side electrode is extracted from a front surface of the framing portion to a back surface of the framing portion, and
the back surface side electrode is disposed to avoid crossing over the stepped portion in a case where the second extraction electrode is disposed across the stepped portion.

5. The piezoelectric vibrating piece according to claim 2, wherein
the first extraction electrode includes a back surface side electrode, and the back surface side electrode is extracted from a front surface of the framing portion to a back surface of the framing portion, and
the back surface side electrode is disposed to avoid crossing over the stepped portion in a case where the second extraction electrode is disposed across the stepped portion.

6. The piezoelectric vibrating piece according to claim 3, wherein
the first extraction electrode includes a back surface side electrode, and the back surface side electrode is extracted from a front surface of the framing portion to a back surface of the framing portion, and
the back surface side electrode is disposed to avoid crossing over the stepped portion in a case where the second extraction electrode is disposed across the stepped portion.

7. A piezoelectric device, comprising
the piezoelectric vibrating piece according to claim 1.

8. A piezoelectric device, comprising
the piezoelectric vibrating piece according to claim 2.

9. A piezoelectric device, comprising
the piezoelectric vibrating piece according to claim 3.

10. A piezoelectric device, comprising
the piezoelectric vibrating piece according to claim 4.

11. A piezoelectric device, comprising
the piezoelectric vibrating piece according to claim 5.

12. A piezoelectric device, comprising
the piezoelectric vibrating piece according to claim 6.
